(19) United States
(12) Patent Application Publication
(10) Pub. No.: US 2026/0343077 A1
(43) Pub. Date: Oct. 29, 2026

(54) IMAGING UNIT AND IMAGE PICKUP APPARATUS

(71) Applicant: CANON KABUSHIKI KAISHA, Tokyo (JP)

(72) Inventor: KEISUKE ADACHI, Tokyo (JP)

(21) Appl. No.: 19/645,990

(22) Filed: Apr. 13, 2026

(30) Foreign Application Priority Data
Apr. 24, 2025 (JP) 2025-072348

(51) Int. Cl. H04N 23/52; H04N 23/54; H05K 1/02; H05K 1/14

(52) U.S. Cl. CPC H04N 23/52; H04N 23/54; H05K 1/0203; H05K 1/147; H05K 2201/10151

(57) ABSTRACT

An image sensor unit may include an image sensor, a first substrate mounted with the image sensor, a second substrate electrically connected to the first substrate and configured to supply power to the first substrate, a holding member movable in a direction orthogonal to an optical axis and configured to hold the first substrate and the second substrate, and a heat dissipating plate fixed to the holding member. The first substrate, the second substrate, and the heat dissipating plate may be arranged in this order from an image-sensor side along the optical axis. The heat dissipating plate may include a region that overlaps an electrical connector between the first substrate and the second substrate when viewed in a direction along the optical axis.

### BACKGROUND

### Field of the Technology

The present disclosure relates to an imaging unit having an image stabilizing mechanism, and an image pickup apparatus having the imaging unit.

### DESCRIPTION OF THE RELATED ART

Along with an increased readout speed and an increased pixel count on an image sensor, the amount of current flowing through a flexible printed circuit (substrate) (FPC) connected to an image sensor increases and thereby causes problems such as image degradation due to magnetic radiation. Japanese Patent No. 7074706 discloses a configuration that includes a shielding portion provided in a sheet metal member disposed between substrates, thereby improving the shielding performance against magnetic noise applied to the image sensor due to current flowing through the FPC. In addition to the imaging substrate mounted with the image sensor, a configuration is also known in which a substrate mounted with a DC-DC converter is connected to the imaging substrate via a board-to-board connector, thereby suppressing the influence of magnetic radiation.

However, the configuration disclosed in Japanese Patent No. 7074706 places the shielding portion so as to cover a side surface of the substrate, and thus the thickness tends to increase. Since the substrates are connected by the FPC, the influence of magnetic noise remains significant. The configuration that connects the substrate mounted with the DC-DC converter and the imaging substrate via a board-to-board connector may have a concern of momentary disconnection, when vibration or impact is applied, at the board-to-board connector, thereby interrupting power supply to the image sensor and causing destruction of captured images or the like.

### SUMMARY

An image sensor unit according to one aspect of the present disclosure may include an image sensor, a first substrate mounted with the image sensor, a second substrate electrically connected to the first substrate and configured to supply power to the first substrate, a holding member movable in a direction orthogonal to an optical axis and configured to hold the first substrate and the second substrate, and a heat dissipating plate fixed to the holding member. The first substrate, the second substrate, and the heat dissipating plate may be arranged in this order from an image-sensor side along the optical axis. The heat dissipating plate may include a region that overlaps an electrical connector between the first substrate and the second substrate when viewed in a direction along the optical axis. An image pickup apparatus having the above image sensor unit also constitutes another aspect of the present disclosure.

Features of the present disclosure will become apparent from the following description of embodiments with reference to the attached drawings. The following description of embodiments will be described by way of example.

### BRIEF DESCRIPTION OF THE DRAWINGS

FIGS. 1A and 1B are exploded perspective views of an image pickup apparatus according to a first embodiment.

FIGS. 2A and 2B are exploded perspective views of an image sensor unit according to the first embodiment.

FIGS. 3A and 3B are explanatory views of a movable unit according to the first embodiment.

FIGS. 4A, 4B, and 4C are explanatory views of the image sensor unit according to the first embodiment.

FIGS. 5A and 5B are exploded perspective views of an image sensor unit according to a second embodiment.

FIGS. 6A and 6B are explanatory views of a movable unit according to the second embodiment.

### DESCRIPTION OF THE EMBODIMENTS

Referring now to the accompanying drawings, a detailed description will be given of embodiments according to the present disclosure. Corresponding elements in respective figures will be designated by the same reference numerals, and a duplicate description thereof will be omitted.

### FIRST EMBODIMENT

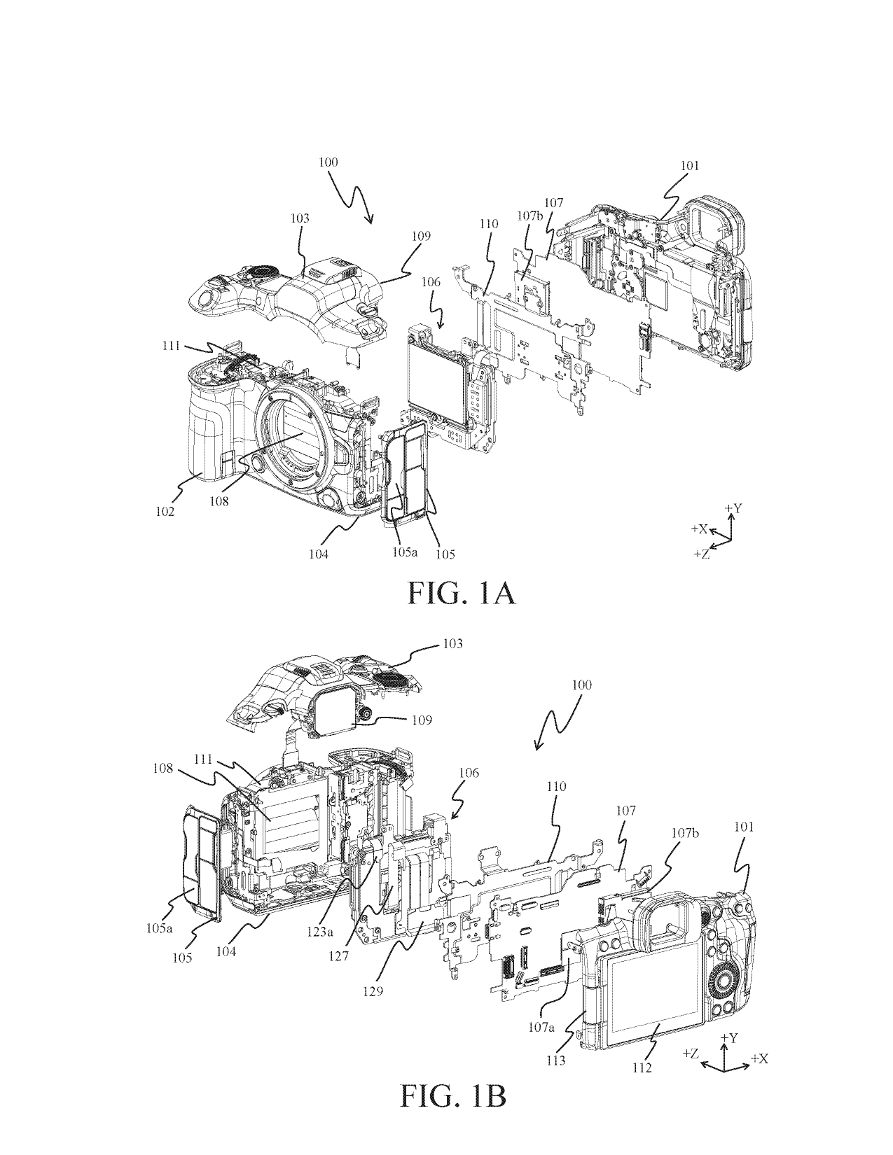

FIGS. 1A and 1B are exploded perspective views of a digital camera 100, which is an example of an image pickup apparatus according to the present embodiment. FIG. 1A is an exploded perspective view when the digital camera 100 is viewed from a front side (an object side). FIG. 1B is an exploded perspective view when the digital camera 100 is viewed from a rear side (an image plane side). A Z direction is an optical-axis direction (a direction orthogonal to an imaging surface of an image sensor).

The digital camera 100 includes a rear cover 101, a front cover 102, a top cover 103, a bottom cover 104, and a side cover 105. The digital camera 100 further includes an image sensor unit (imaging unit) 106, a main substrate 107, a shutter 108, a finder (viewfinder9 109, a chassis 110, a front base 111, and an imaging flexible printed circuit (board) (FPC) 109.

The front base 111 is made of, for example, magnesium die cast or resin.

The main substrate 107 is a multilayer substrate, and electronic components are mounted on both surfaces thereof. The main substrate 107 is fastened to the front base 111 and the chassis 110 with screws. A control IC 107a for controlling imaging signals and the like, and a recording-medium connector 107b for accommodating an external recording medium are mounted on the main substrate 107.

The side cover 105 includes a terminal cover 105a that covers interface terminals.

The imaging FPC 129 electrically connects the image sensor unit 106 and the main substrate 107.

The image sensor unit 106 is fastened to the front base 111 with screws. The image sensor unit 106 includes an image sensor 121 and an image stabilizing mechanism. The image stabilizing mechanism moves the image sensor 121 in a direction orthogonal to the optical axis for shake correction.

The rear cover 101 holds a liquid crystal display unit 112 so as to be pivotable by a hinge 113.

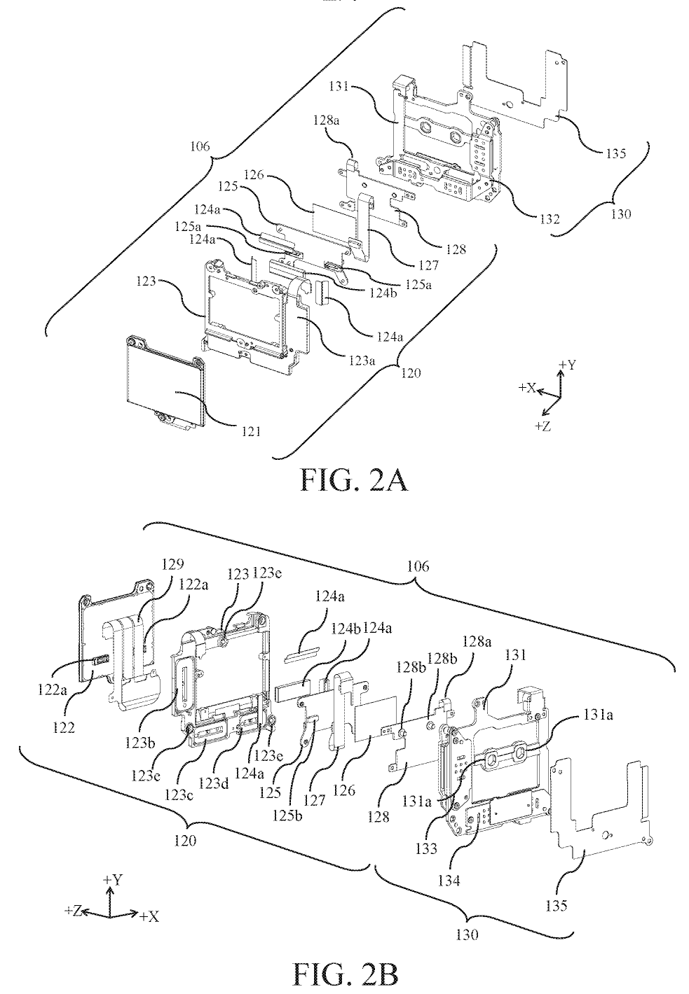

The image sensor unit 106 will be described below with reference to FIGS. 2A and 2B. FIGS. 2A and 2B are exploded perspective views of the image sensor unit 106 according to the present embodiment. FIG. 2A is an exploded perspective view when the image sensor unit 106 is viewed from the front side. FIG. 2B is an exploded perspective view when the image sensor unit 106 is viewed from the rear side.

The image sensor unit 106 includes a movable unit 120 and a fixed portion (fixed member) 130. The movable unit 120 includes an imaging substrate 122, a movable frame (holding member) 123, an imaging power substrate 125, an imaging power FPC 127, and a movable-unit heat dissipating plate 128, and is configured to be movable in a direction orthogonal to the optical axis. That is, in the present embodiment, the movable unit 120 functions as the image stabilizing mechanism. The fixed portion 130 includes a fixed frame 131, a front yoke 132, a first rear yoke 133, a second rear yoke 134, and a fixed-portion heat dissipating plate 135.

The movable frame 123 includes an FPC 123a and a ball holder 123e. Coils (a first coil 123b, a second coil 123c, and a third coil 123d) for moving the movable unit 120 and Hall elements are mounted on the FPC 123a. Balls are placed in the ball holder 123e.

The fixed frame 131 holds three magnets at positions facing the coils (the first coil 123b, the second coil 123c, and the third coil 123d). The movable unit 120 is attracted and held toward the fixed portion 130 by the magnets held by the fixed frame 131. A distance between the movable unit 120 and the fixed portion 130 is kept constant by the balls placed in the ball holder 123e. Thus, the movable unit 120 is held so as not to be affected by friction.

The front yoke 132, the first rear yoke 133, and the second rear yoke 134 are fixed to the fixed frame 131 with screws. A magnetic circuit is formed by sandwiching each of the three magnets with the yokes. The movable unit 120 can be moved by changing an amount of current supplied to the coils (the first coil 123b, the second coil 123c, and the third coil 123d). Image stabilization can be performed by moving the movable unit 120 in a direction that cancels shake of the digital camera 100.

The imaging substrate 122 is adhesively fixed to the movable frame 123. The image sensor 121 is mounted on the imaging substrate 122. Elements such as capacitors, resistors, and a regulator of an imaging circuit, and a board-to-board connector 122a are mounted on a rear surface of a surface of the imaging substrate 122 on which the image sensor 121 is mounted.

A DC-DC converter and a board-to-board connector 125a to be connected to the board-to-board connector 122a are mounted on the imaging power substrate 125. The imaging power substrate 125 is fixed to the movable frame 123 with screws.

The imaging power FPC 127 electrically connects to the main substrate 107 via a board-to-board connector 125b provided on the imaging power substrate 125.

The imaging substrate 122 and the movable frame 123 are thermally connected by a heat dissipating sheet 124a. The imaging substrate 122 and the imaging power substrate 125 are thermally connected by a heat dissipating sheet 124b.

The movable-unit heat dissipating plate 128 is fixed to the movable frame 123 with screws. A heat dissipating sheet (elastic member) 126 having a shape that avoids mounted components such as the board-to-board connector 125a is disposed between the imaging power substrate 125 and the movable-unit heat dissipating plate 128. The imaging power substrate 125 and the movable-unit heat dissipating plate 128 are thermally connected by the heat dissipating sheet 126. The heat dissipating sheet 126 is made of, for example, a heat-dissipating rubber having high thermal conductivity, and is fixed in a compressed state.

The imaging substrate 122 and the main substrate 107 are electrically connected via the imaging power substrate 125, the imaging power FPC 127, and the imaging FPC 129. The FPC 123a is also electrically connected to the main substrate 107 and supplies power to the coils (the first coil 123b, the second coil 123c, and the third coil 123d).

An imaging signal output from the image sensor 121 is transmitted to the control IC 107a via the imaging FPC 129.

The imaging FPC 129, the imaging power FPC 127, and the FPC 123a include U-turn portions. The U-turn portions can absorb displacement when the movable unit 120 moves, suppress interference with movement of the movable unit 120 due to the stiffness of the imaging FPC 129, the imaging power FPC 127, and the FPC 123a, and restrain wire breakage.

As described above, the imaging substrate 122 and the imaging power substrate 125 are electrically directly connected by the board-to-board connectors 122a and 125a, and the imaging power substrate 125 is connected to the main substrate 107 via the imaging power FPC 127. Therefore, the current flowing from the main substrate 107 to the imaging power FPC 127 can be kept low by setting the voltage high. Thereafter, stepping down the voltage with the DC-DC converter mounted on the imaging power substrate 125 can supply a proper current to the imaging substrate 122. In this manner, since the current flowing through the imaging power FPC 127 can be kept low, the influence of noise on the image sensor 121 due to magnetic radiation can be suppressed.

The fixed-portion heat dissipating plate 135 is fixed to the fixed frame 131 with screws. The movable-unit heat dissipating plate 128 and the fixed-portion heat dissipating plate 135 are thermally connected by a heat dissipating sheet 128a. The heat dissipating sheet 128a includes a U-turn portion. This structure absorbs displacement when the movable unit 120 moves, and suppress interference with movement of the movable unit 120 due to stiffness of the heat dissipating sheet 128a.

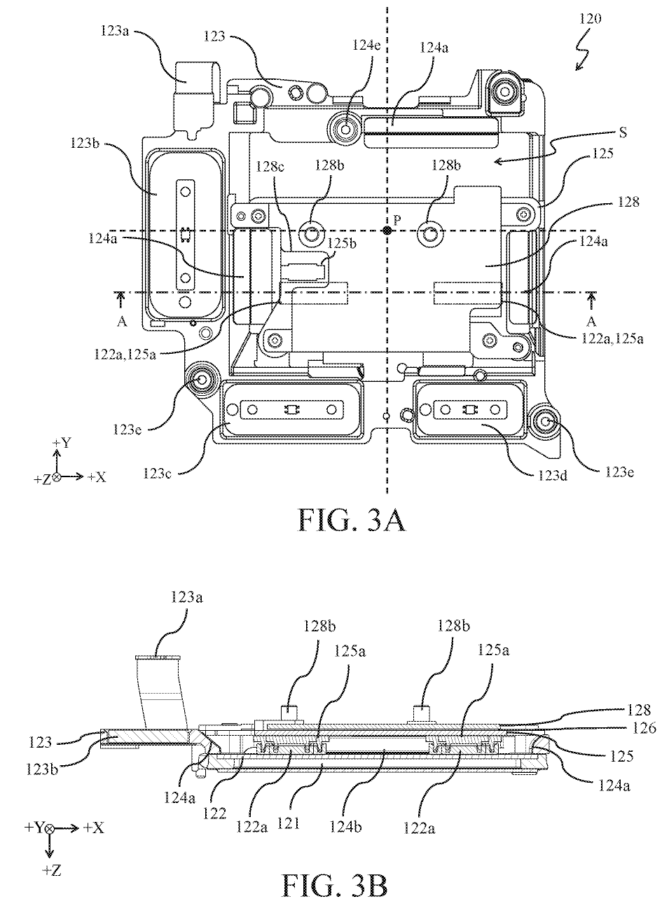

The movable unit 120 will be described in detail below. FIGS. 3A and 3B are explanatory views of the movable unit 120 according to the present embodiment. FIG. 3A is a rear view of the movable unit 120. FIG. 3B is a sectional view taken along line A-A of FIG. 3A.

Two stopper pins 128b are fixed to the movable-unit heat dissipating plate 128 by caulking. The stopper pins 128b restrict the movable unit 120 from moving more than necessary when vibration or impact such as a drop is applied to the digital camera 100.

The movable-unit heat dissipating plate 128 has a notch portion 128c to avoid the board-to-board connector 125b of the imaging power substrate 125.

The imaging power substrate 125 and the movable-unit heat dissipating plate 128 are disposed in a shape having a non-uniform width in a Y direction (parallel to a short side of the imaging substrate 122) with respect to an optical-axis center P. More specifically, a width in a +Y direction is smaller than a width in a -Y direction. Thus, space S is formed along the Z direction on a +Y direction side of the imaging power substrate 125, the movable-unit heat dissipating plate 128, and the movable frame 123.

When viewed from the direction of FIG. 3A, the movable-unit heat dissipating plate 128 is disposed so as to cover a range of an electrical connector (the board-to-board connectors 122a and 125a) that electrically connects the imaging substrate 122 and the imaging power substrate 125. That is, when viewed from the direction of FIG. 3A, the movable-unit heat dissipating plate 128 includes a region overlapping the board-to-board connectors 122a and 125a.

The image sensor 121, the imaging substrate 122, the heat dissipating sheet 124b, the imaging power substrate 125, the heat dissipating sheet 126, and the movable-unit heat dissipating plate 128 are arranged in the Z direction in order from a plus side to a minus side (along an upward direction in FIG. 3B).

As described above, since the movable-unit heat dissipating plate 128 is disposed so as to cover the board-to-board connectors 122a and 125a, the imaging power substrate 125 can be pressed when vibration or impact such as a drop is applied to the digital camera 100. This configuration can restrain the board-to-board connector 125a from being disengaged from the board-to-board connector 122a due to deformation of the imaging power substrate 125 in the Z direction, thereby prevent interruption of electrical connection, and improve stable connection between the substrates.

In order to improve the stable connection of the board-to-board connectors 122a and 125a, the movable-unit heat dissipating plate 128 may be disposed so as to cover at least the connectors. The notch portion 128c may be provided so that mounted components such as the board-to-board connector 125b can be provided on the imaging power substrate 125.

Since the heat dissipating sheet 126 formed of silicone rubber or the like having high elasticity is provided between the imaging power substrate 125 and the movable-unit heat dissipating plate 128, a shift of the imaging power substrate 125 in XY directions can be restricted by elasticity of the heat dissipating sheet 126. Therefore, the stable connection of the board-to-board connectors 122a and 125a can be further improved.

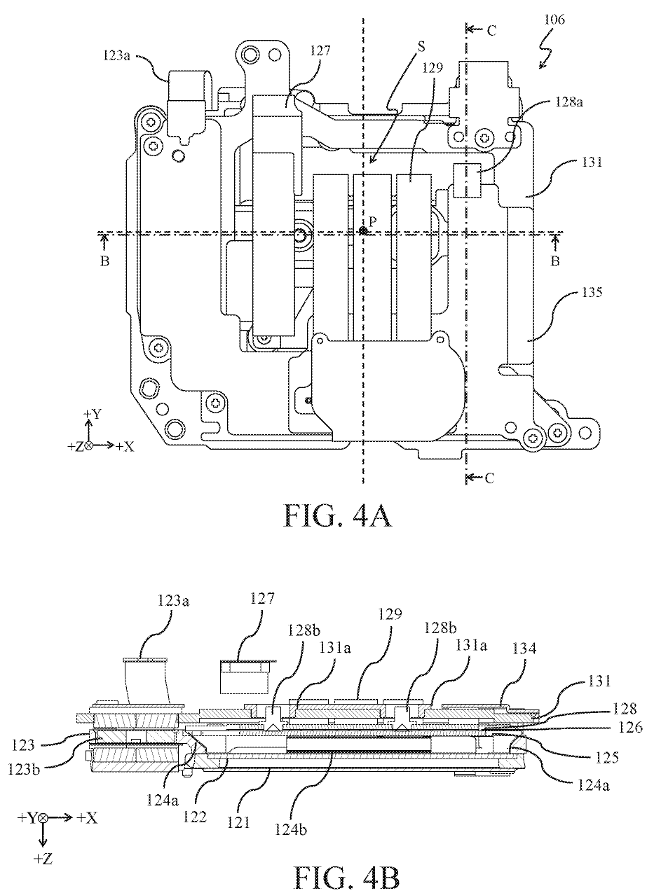

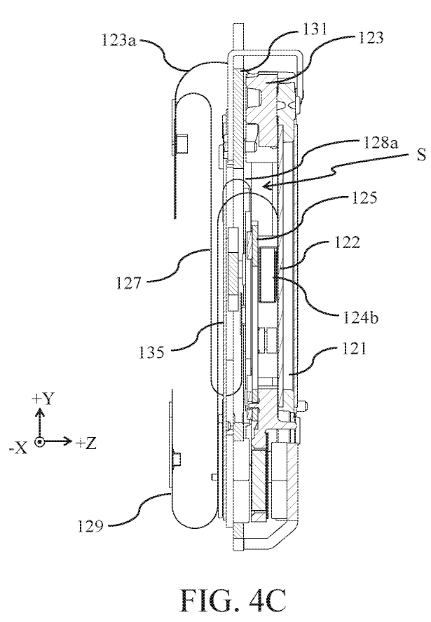

The image sensor unit 106 will be described in detail below with reference to FIGS. 4A, 4B, and 4C, . FIGS. 4A, 4B, and 4C, are explanatory views of the image sensor unit 106. FIG. 4A is a rear view of the image sensor unit 106. FIG. 4B is a sectional view taken along line B-B of FIG. 4A. FIG. 4C is a sectional view taken along line C-C of FIG. 4A.

As illustrated in FIG. 4A, the FPC 123a, the imaging power FPC 127, the imaging FPC 129, and the heat dissipating sheet 128a are arranged so as not to overlap one another on the XY plane.

As described above, the imaging power substrate 125 and the movable-unit heat dissipating plate 128 arranged in a shape having a non-uniform width in the Y direction with respect to the optical-axis center P and providing the space S can achieve a non-overlapping arrangement on the XY plane.

As illustrated in FIG. 4C, each of the FPC 123a, the imaging power FPC 127, the imaging FPC 129, and the heat dissipating sheet 128a includes a U-turn portion (bent portion). By arranging the U-turn portions of the FPC 123a, the imaging power FPC 127, the imaging FPC 129, and the heat dissipating sheet 128a so as not to overlap one another on the XY plane, each U-turn portion can be made longer and larger. Thus, a load on movement of the movable unit 120 can be further reduced.

The U-turn portions of the imaging FPC 129 and the heat dissipating sheet 128a provided within the space S can be made longer and larger.

A stopper portion 131a is provided on the fixed frame 131. The stopper pin 128b is inserted into the stopper portion 131a with a gap therebetween. A gap amount is set larger than a moving amount required for the movable unit 120 for image stabilization. Thereby, only when impact is applied to the digital camera 100 due to vibration, a drop, or the like, the stopper portion 131a contacts the stopper pin 128b to restrict the movable unit 120 from moving more than necessary.

The heat dissipating sheet 124a transmits the heat of the imaging substrate 122 to the movable frame 123. Since the movable-unit heat dissipating plate 128 is fixed to the movable frame 123 with screws, the heat transmitted to the movable frame 123 is transmitted to the movable-unit heat dissipating plate 128.

The heat dissipating sheet 124b transmits the heat of the imaging substrate 122 to the imaging power substrate 125. The heat transmitted to the imaging power substrate 125 is transmitted to the movable-unit heat dissipating plate 128 via the heat dissipating sheet 126.

As described above, the present embodiment collects the heat of the imaging substrate 122 in the movable-unit heat dissipating plate 128. The heat collected in the movable-unit heat dissipating plate 128 is transmitted to the fixed-portion heat dissipating plate 135 via the heat dissipating sheet 128a.

Transmitting the heat transmitted to the fixed-portion heat dissipating plate 135 to the chassis 110 using a heat dissipating member (not illustrated) can diffuse heat of the imaging substrate 122 and the imaging power substrate 125 inside the digital camera 100. Thereby, thermal influence on captured images can be suppressed and/or a moving image capturing time can be extended.

### SECOND EMBODIMENT

A basic configuration of the digital camera 100 according to the present embodiment is similar to that of the digital camera 100 according to the first embodiment. The present embodiment will discuss only configurations different from those of the first embodiment, and will omit a description of common configurations.

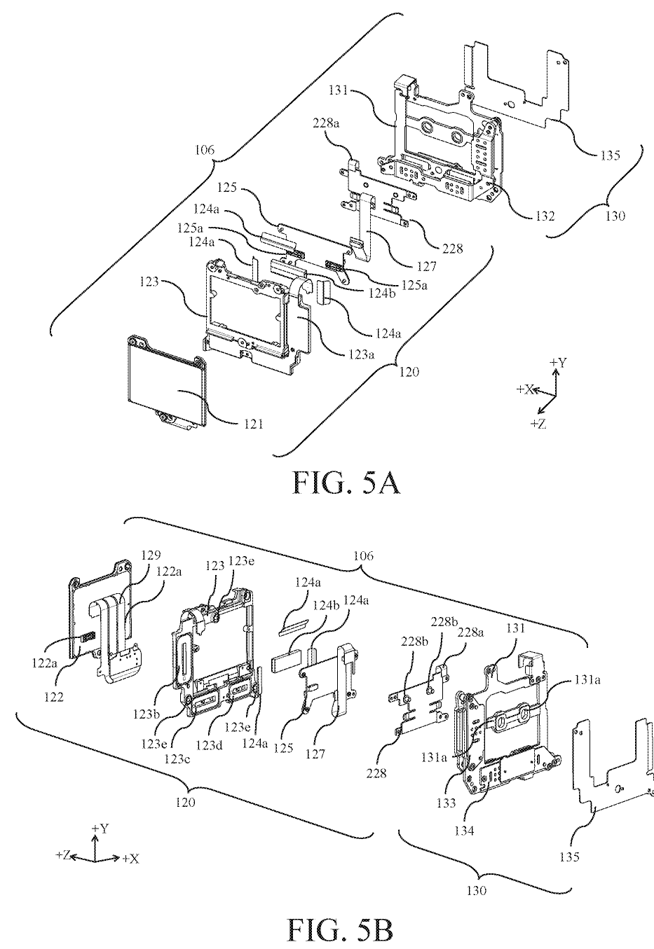

FIGS. 5A and 5B are exploded perspective views of the image sensor unit 106 according to the present embodiment. FIG. 5A is an exploded perspective view when the image sensor unit 106 is viewed from the front side. FIG. 5B is an exploded perspective view when the image sensor unit 106 is viewed from the rear side.

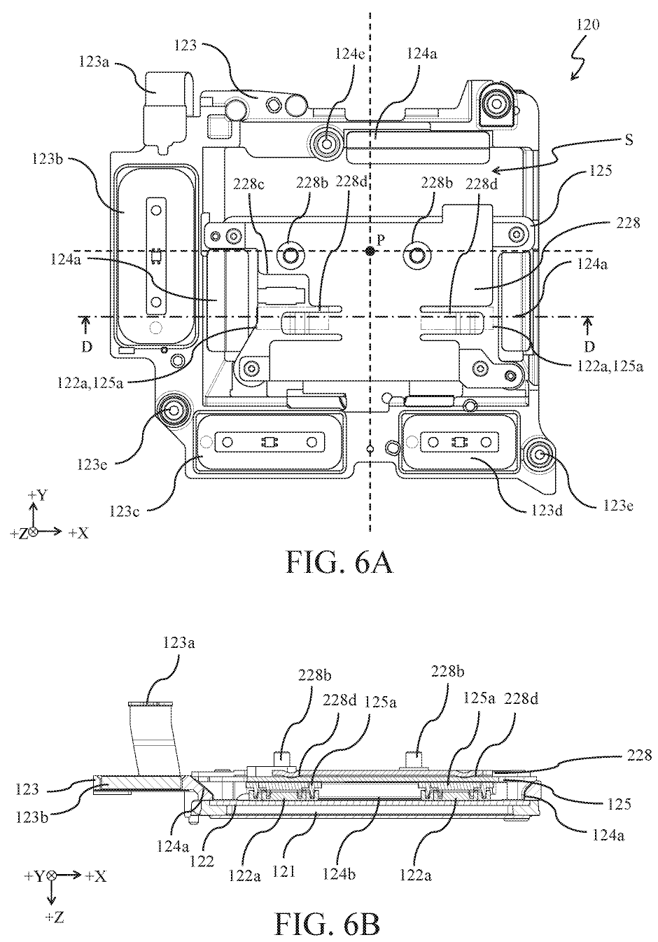

FIGS. 6A and 6B are explanatory views of the movable unit 120 according to the present embodiment. FIG. 6A is a rear view of the movable unit 120. FIG. 6B is a sectional view taken along line D-D of FIG. 6A.

A movable-unit heat dissipating plate 228 is fixed to the movable frame 123 with screws. The movable-unit heat dissipating plate 228 and the fixed-portion heat dissipating plate 135 are thermally connected by a heat dissipating sheet 228a. The heat dissipating sheet 228a includes a U-turn portion, absorbs displacement when the movable unit 120 moves, and can suppress interference with movement of the movable unit 120 due to the stiffness of the heat dissipating sheet 228a.

Two stopper pins 228b are fixed to the movable-unit heat dissipating plate 228 by caulking. The stopper pins 228b restrict the movable unit 120 from moving more than necessary when vibration or impact such as a drop is applied to the digital camera 100.

The movable-unit heat dissipating plate 228 is provided with a notch portion 228c to avoid the board-to-board connector 125b of the imaging power substrate 125.

When viewed from the direction of FIG. 6A, the movable-unit heat dissipating plate 228 includes a pressing portion 228d that presses the position overlapping a range of the board-to-board connectors 122a and 125a that electrically connect the imaging substrate 122 and the imaging power substrate 125. The pressing portion 228d presses the imaging power substrate 125 in a +Z direction by charging an arm portion. Therefore, in a case where vibration or impact such as a drop is applied to the digital camera 100, the pressing portion 228d can press the imaging power substrate 125. This configuration can suppress the board-to-board connector 125a from being disengaged from the board-to-board connector 122a due to deformation of the imaging power substrate 125 in the Z direction, prevent interruption of electrical connection, and improve stable connection between the substrates.

Since an elastic member such as the heat dissipating sheet 126 can be omitted, the stable connection can be improved more simply. However, an elastic member such as the heat dissipating sheet 126 may be disposed.

While the present disclosure has been described with reference to embodiments, it is to be understood that the present disclosure is not limited to the disclosed embodiments. The scope of the following claims is to be accorded the broadest interpretation so as to encompass all such modifications and equivalent structures and functions.

Each embodiment can provide an image sensor unit that can improve stable connection between substrates while suppressing image degradation due to magnetic radiation.

This application claims the benefit of Japanese Patent Application No. 2025-072348, filed on April 24, 2025, which is hereby incorporated by reference herein in its entirety.

What is claimed is:

1. An image sensor unit comprising:
an image sensor;
a first substrate mounted with the image sensor;
a second substrate electrically connected to the first substrate and configured to supply power to the first substrate;
a holding member movable in a direction orthogonal to an optical axis and configured to hold the first substrate and the second substrate; and
a heat dissipating plate fixed to the holding member,
wherein the first substrate, the second substrate, and the heat dissipating plate are arranged in this order from an image-sensor side along the optical axis, and
wherein the heat dissipating plate includes a region that overlaps an electrical connector between the first substrate and the second substrate when viewed in a direction along the optical axis.

2. The image sensor unit according to claim 1, wherein the first substrate and the second substrate are connected by a board-to-board connector.

3. The image sensor unit according to claim 1, further comprising an elastic member disposed between the region of the heat dissipating plate and the second substrate.

4. The image sensor unit according to claim 1, further comprising a fixed member configured to movably support the holding member in the direction orthogonal to the optical axis,
wherein the heat dissipating plate includes a heat dissipating member that is bent and connects the heat dissipating plate and the fixed member.

5. The image sensor unit according to claim 4, further comprising a flexible printed circuit bent and connected to the first substrate or the second substrate,
wherein the second substrate has a non-uniform width from an optical-axis center in a direction parallel to a short side of the first substrate, and
wherein a bent portion of the flexible printed circuit and a bent portion of the heat dissipating member overlap the first substrate and do not overlap the second substrate when viewed in the direction along the optical axis.

6. The image sensor unit according to claim 5, wherein the flexible printed circuit is disposed so as not to overlap the heat dissipating member when viewed in the direction along the optical axis.

7. The image sensor unit according to claim 1, wherein the region of the heat dissipating plate includes a pressing portion configured to press the second substrate.

8. An image pickup apparatus comprising:
an image sensor unit that includes:
an image sensor;
a first substrate mounted with the image sensor;
a second substrate electrically connected to the first substrate and configured to supply power to the first substrate;
a holding member movable in a direction orthogonal to an optical axis and configured to hold the first substrate and the second substrate; and
a heat dissipating plate fixed to the holding member,
wherein the first substrate, the second substrate, and the heat dissipating plate are arranged in this order from an image-sensor side along the optical axis, and
wherein the heat dissipating plate includes a region that overlaps an electrical connector between the first substrate and the second substrate when
viewed in a direction along the optical axis.
